(19) United States
(12) Patent Application Publication
(10) Pub. No.: US 2010/0190034 A1
(43) Pub. Date: Jul. 29, 2010

(54) SURFACE TREATMENT, SURFACE-TREATED HEAD SLIDER OR MAGNETIC RECORDING MEDIUM, AND MAGNETIC RECORDING-REPRODUCING DEVICE

(75) Inventors: Yoshiaki IKAI, Kawasaki (JP); Hiroshi Chiba, Kawasaki (JP); Susumu Ogata, Kawasaki (JP); Masayuki Takeda, KawasakI (JP)

Correspondence Address: SUGHRUE MION, PLLC, 2100 PENNSYLVANIA AVENUE, N.W., SUITE 800, WASHINGTON, DC, 20037, US

(73) Assignee: Showa Denko K.K., Tokyo (JP)

(21) Appl. No.: 12/565,514

(22) Filed: Sep. 23, 2009

(30) Foreign Application Priority Data
Sep. 25, 2008 (JP) 2008-245287
Apr. 10, 2009 (JP) 2009-96078

(51) Int. Cl. G11B 5/33; C23C 16/44

(52) U.S. Cl. 428/810; 428/800; 427/595

(57) ABSTRACT

A novel technology for lowering the surface free energy is provided. A treatment surface is irradiated with ultraviolet light in a gas containing a fluorine-containing organic substance, thereby forming a coating layer on the treatment surface.

### BACKGROUND OF THE INVENTION

1. Field of the Invention

The following embodiments relate to surface treatment in general, and more particularly relate to fields that require ultrathin film surface treatment, such as general electronic devices, head sliders or magnetic recording media for magnetic recording/playback devices, and Microelectromechanical Systems (MEMS). As used herein, a “magnetic recording/playback device” refers to a device which can carry out either or both magnetic recording and playback of the magnetic recording. Such a device includes therein at least one of a head slider and a magnetic recording medium.

2. Description of the Related Art

In a magnetic recording/playback device, a head slider having a recording transducer (also referred to simply as a “head”) carries out information read/write while floating over a hard disk serving as the magnetic recording medium.

The distance between the head and the magnetic layer for recording (writing) or playing back (reading) magnetic information on the hard disk is called the “magnetic spacing.” A smaller magnetic spacing results in an increase in recording density. For this reason, to address the strong need recently for increased recording densities, the head floating height, or “head gap,” today is close to breaking the 10 nm barrier. With such an ultralow floating gap, the floating stability of the head is greatly disrupted by the deposition of merely a slight amount of contaminant on the head slider.

One type of contaminant is known to be volatile organic substances and debris brought in from the surrounding environment. With operation of the head slider, such volatile organic substances and debris adhered to the hard disk were collected onto the head slider, ultimately filling the head floating gap and leading to a head crash.

Also, as the float height of the head slider decreases, liquid lubricant coated on the recording medium and freely suspended contaminants within the device adhere to the floating surface of the head slider, giving rise to contact between the head slider and the recording medium, which causes problems that trigger serious malfunctions such as a head crash.

Recently, due in part to the mounting of a thermal expansion actuator on the head slider, opportunities for contact between the head slider and the recording medium have increased, resulting in a greater danger that excessive friction at the time of contact will lead to head slider malfunction.

Various methods for resolving the above problems have been proposed. For example, a method has been devised which involves patterning the head slider surface that faces the magnetic recording medium (also referred to simply as the “head slider surface”) so as to reduce the surface free energy and thereby inhibit contaminant adhesion (see the claims of Japanese Patent Application Laid-open No. H9-219077). However, this method has the drawback of increased production costs for the head slider.

Also, a method for lowering the surface free energy by providing a self-organizing film on the head slider surface has been described (see the claims of Japanese Patent Application Laid-open No. H11-16313). However, the self-organizing film itself has a large film thickness (molecular chain length), which increases the magnetic spacing and is inappropriate for achieving a higher recording density. Moreover, the fact that the self-organizing film employed in this method contains silicon, a substance known for its tendency to trigger head crashes, is an obstacle to the practical use of this method.

In addition, there has been proposed a method for lowering the surface free energy and reducing contaminant adhesion by applying to the head slider surface or the surface of a head slider protective layer (also referred to as a “head protective layer”) a lubricant identical or similar to the lubricant applied onto the hard disk, then irradiating ultraviolet light (see the claims of Japanese Patent Application Laid-open No. H7-85438).

An exceptional feature of this method is the use of ultraviolet light to fix in place the lubricant applied onto the head slider, thereby converting the lubricant from a liquid to a solid film and making it difficult for liquid bridging to arise. However, when a lubricant with molecular ends having polarity as disclosed in this prior-art document is simply applied in this way, the lubricant ends up aggregating under cohesive forces and, with UV treatment, solidifies in this state. As a result, not only do coating irregularities arise, the height of the aggregated lubricant fills the head gap, which may cause floating malfunctions such as the inability of the head slider to float, a head crash, or scratching of the magnetic recording medium. Also, depending on the degree of UV treatment, some portions of the head slider lubricating layer (also called “head lubricating layer”) may be present as a liquid, in which portions liquid bridging will still arise, making it impossible to achieve the desired effect.

An additional challenge is the need, in order to reduce the magnetic spacing, to make the film of lubricant that has applied onto the magnetic recording medium thin.

### SUMMARY OF THE INVENTION

As mentioned above, it is difficult to reduce the adhesion of contaminants to the head slider and at the same time to achieve an ultra-low float characteristics for the head slider. In addition, there is also the problem of aggregation of the resin that forms the head lubricating layer. A need exists for solutions to these problems. It is therefore an object of the embodiments in the present specification to resolve these problems and provide art which reduces contaminant adhesion on the head slider and prevents aggregation of the resin that forms the head lubricating layer, and which also achieves ultra-low floating characteristics for the head slider. Another object is to provide art useful in applications that generally require a uniform surface having a low surface free energy, as exemplified by the lubricating film on a magnetic recording medium. Further objects and advantages of the embodiments in this specification will become apparent from the following description.

It has been discovered that a surface treatment method which includes the step of irradiating a treatment surface with ultraviolet light in a gas containing a fluorine-containing organic substance so as to form a coating layer on the treatment surface is useful for achieving the above objects.

Objects having a surface created by such a surface treatment method have a number of advantages. For example, they provide a uniform surface having a low surface free energy, discourage the adhesion of contaminants, and enable the formation of an ultrathin layer. Such an approach may be advantageously employed in, for example, methods of manufacturing lubricating layers on the head sliders and magnetic recording media used in a magnetic recording/playback devices, and applications for such lubricating layers.

It has been also discovered that a head slider having a recording transducer for carrying out recording to and/or playback from a magnetic recording medium, and also having a head slider protective layer on the head slider on a side facing the magnetic recording medium, and a covering formed on the head slider protective layer and including fluorine-containing organic structures composed of small molecules having a number of constituent atoms following deposition of three or four is also useful for achieving the above objects.

Because such a head slider has on the surface an ultrathin layer with a low surface free energy that discourages the adhesion of contaminants, it is well-suited for use in magnetic recording/playback devices which employ a system wherein, following detection of the relative position of the head slider with respect to a recording medium by contact between the magnetic recording/playback device, particularly a portion of the head slider, and the recording medium, information recording to the recording medium or information playback from the recording medium is carried out with the head slider and the recording medium in a non-contact state, and in magnetic recording/playback devices which employ a system wherein information recording to a recording medium or information playback from a recording medium is carried out with a portion of the head slider in contact with the recording medium.

Novel methods which lower the surface free energy are provided by means of the following embodiments. As a result, there can be obtained a uniform ultrathin film which may be employed as a lubricity-conferring film (lubricating layer) suitable for use in magnetic recording media and head sliders. Also, regarding the previously unresolved challenges encountered in conventional surface free energy-lowering art, the embodiments below provide solutions to the problems of contaminant adhesion and resin aggregation on such surface free energy-lowered surfaces.

### BRIEF DESCRIPTION OF THE DRAWINGS

FIG. 1 is a schematic diagram depicting how a photoelectron generated by ultraviolet light from a treatment surface causes fluorine in a fluorine-containing organic substance to dissociate, and the carbon which has lost the fluorine to bond chemically to the treatment surface;

FIG. 2 is a schematic diagram showing the molecular structure of a perfluoroalkane;

FIG. 3 is a schematic diagram showing the molecular structure of a perfluoropolyether;

FIG. 4 is a schematic diagram illustrating the surface free energy measuring positions on a treatment surface;

FIG. 5 is a schematic diagram of an apparatus for carrying out surface treatment;

FIG. 6 is a graph showing the relationship between ultraviolet irradiation time and surface free energy;

FIG. 7 is a graph showing the relationship between ultraviolet irradiation time and coating layer thickness;

FIG. 8 is a graph showing the relationship between ultraviolet irradiation time and coating layer thickness;

FIG. 9 is a graph showing the relationship between ultraviolet irradiation time and surface free energy;

FIG. 10 is a graph showing the relationship between surface free energy and film thickness;

FIG. 11 shows photographs of a head slider surface that faces a magnetic recording medium;

FIG. 12 is a diagram showing the head slider film thickness measurement regions;

FIG. 13 is a graph showing the film thickness measurement results in various film thickness measurement regions on a head slider;

FIG. 14 is a schematic diagram showing the molecular state on the floating surface of a head slider A;

FIG. 15 is a schematic diagram showing the molecular state on the floating surface of a head slider B;

FIG. 16 is a schematic diagram showing the molecular state on the floating surface of a head slider C;

FIG. 17 is a schematic diagram showing the molecular state on the floating surface of a head slider D;

FIG. 18 is a schematic diagram showing the molecular state on the floating surface of a head slider E;

FIG. 19 is a schematic diagram showing the molecular state on the floating surface of a head slider F;

FIG. 20 is a schematic diagram showing the molecular state on the floating surface of a head slider G;

FIG. 21 is a schematic diagram showing the molecular state on the floating surface of a head slider H;

FIG. 22 is a schematic diagram showing the molecular state on the floating surface of a head slider I;

FIG. 23 is a schematic diagram showing a recording medium and lubricating film used in numerical analysis for verifying the frictional characteristics;

FIG. 24 is a diagram illustrating the method of numerical analysis for verifying the frictional properties;

FIG. 25 is a graph showing the results of numerical analysis for verifying the frictional characteristics; and

FIG. 26 is a graph comparing the coefficients of friction obtained by numerical analysis.

### DESCRIPTION OF THE PREFERRED EMBODIMENTS

The embodiments in the present specification are described below using diagrams, tables, formulas and examples. These diagrams, tables, formulas and examples, and the description are used to illustrate the invention and are not to be construed as limiting the scope of the invention. It is to be understood that other embodiments may fall within the purview of the present invention insofar as they are in keeping with the spirit of the invention.

It was discovered that when ultraviolet irradiation is carried out on a surface that is to be subjected to surface treatment (also referred to below as the “treatment surface”) in a gas containing a fluorine-containing organic substance, a coating layer which exhibits a low surface free energy (SFE) forms on the treatment surface. Therefore, employing this art to confer lubricity to the surface or increase the surface lubricity, and to prevent contaminant adhesion may be regarded as desirable. Producing a uniform thin film is also possible.

Such qualities can be widely used in applications requiring a low SFE surface. The use of such a coating layer in place of the lubricating layer on a magnetic recording medium or a head slider, or as part of the lubricating layer, is especially advantageous. In such cases, as will be explained subsequently, because the surface has a strong covering power (i.e., bonds firmly to the treatment surface), the foregoing may be regarded as art which provides a solution to the problem of contaminant adhesion to the surface and resin aggregation on the lubricating layer, and which also addresses the need for head sliders having an ultra-low floating height.

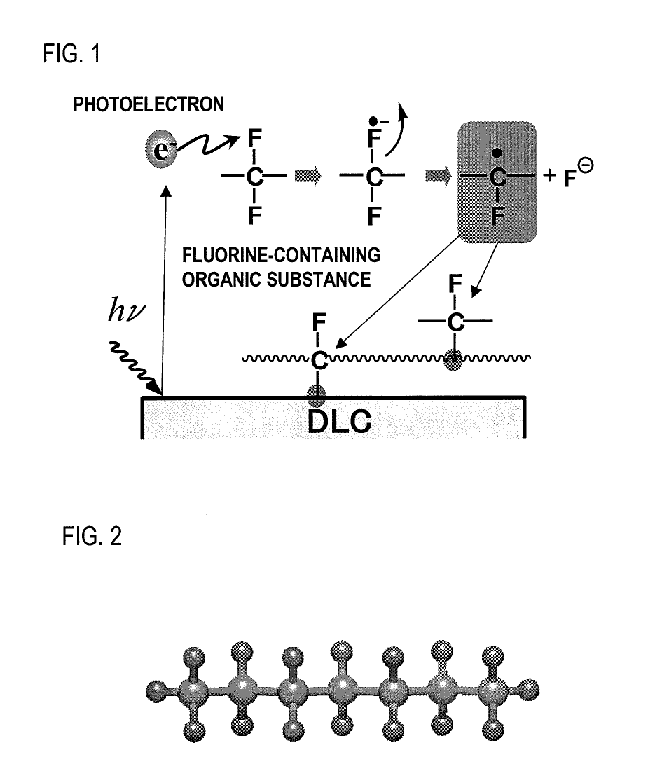

This coating layer bonds firmly to the treatment surface. The reason is thought to be that, as shown in FIG. 1, photoelectrons generated from the treatment surface by ultraviolet light cause the dissociation of fluorine from the fluorine-containing organic substance, as a result of which carbons which have lost such fluorines bond chemically to the treatment surface (in the case shown in FIG. 1, a diamond-like carbon (DLC) surface).

Here, when a low-molecular-weight perfluoroalkane, for example, is used as the fluorine-containing organic substance, a cylindrical structure like that shown in FIG. 2 readily arises, resulting in the arrangement of a carbon skeleton along the treatment surface (which arrangement is sometimes called “horizontal orientation”). This is the most suitable arrangement for making up an ultrathin film.

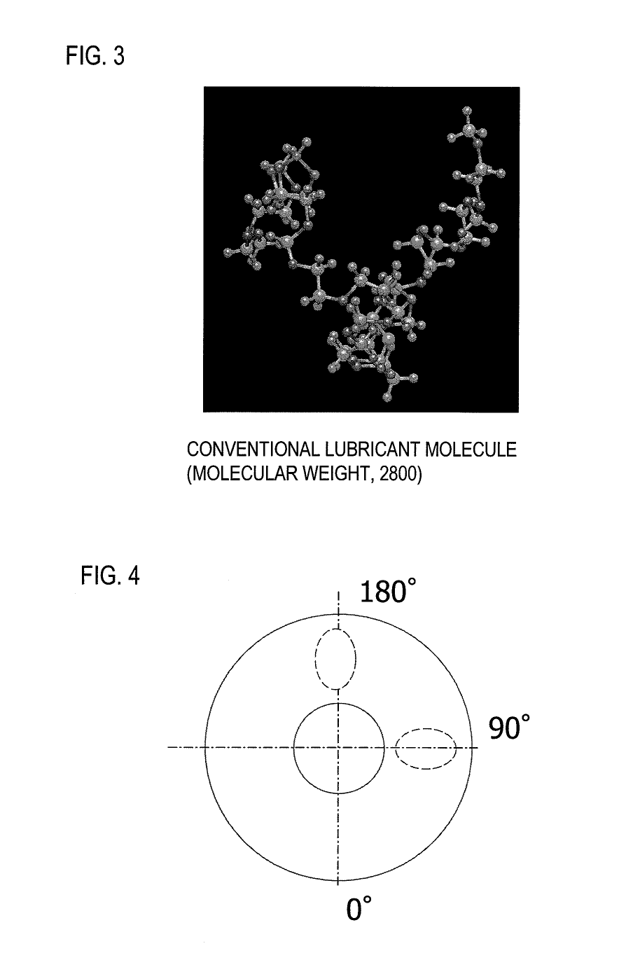

In conventional lubricants used in lubricating layers provided on the protective layer of head sliders and magnetic recording media in magnetic recording/playback devices, because the molecules are gigantic and the degree of freedom is large (see the perfluoropolyether example in FIG. 3), creating an ultrathin film is difficult. Also, in the prior art, polar groups (e.g., carboxyl groups) are often introduced to increase adhesion to the protective layer. However, in such polar groups, the carbon skeleton is positioned at a distance from the surface of the protective layer (such an arrangement is sometimes called “vertical orientation”), which is sometimes undesirable. By contrast, in an arrangement like that shown in FIG. 2, because the molecules are small and there is no need for polar groups, if the carbon skeleton assumes a horizontal orientation, it is arrayed along the treatment surface and thus ideal. Moreover, a coating layer obtained in this way, owing to the perfluoro structure, provides a surface having a low surface free energy. As a result, an ultrathin-film, uniform and low surface free energy surface can be created.

FIG. 1 depicts the dissociation of a fluorine anion radical due to photoelectron attack, and bonding of the remaining carbon radical to the DLC surface. However, this is merely conjecture, and may instead involve some other mechanism.

The fluorine-containing organic substance may be any on which a coating layer will form, although a gaseous substance is preferred because treatment is carried out in a gas. The use of a mist-type substance or a substance in a state comingled with a mist is also possible. If the substance can be rendered into a gas by heating or pressure reduction, the “gaseous fluorine-containing organic substance” requirement may be satisfied by employing such a condition.

In general, a substance which can be rendered into a gas at about standard pressure and room temperature is easy to use. Examples of such substances include fluorinated alkanes having from 1 to 10 carbons, fluorinated alkenes having from 1 to 10 carbons, and corresponding ethers having an oxygen between carbons thereon. Mixtures of these are also acceptable. The fluorinated alkanes and fluorinated alkenes may have a branched structure, although in the interest of minimizing the degree to which the molecules rise out from the treatment surface, a linear structure is preferred. Fewer hydrogens in the fluorinated alkane and fluorinated alkene is often preferable. Specifically, it is preferable for the ratio of hydrogens to the combined amount of fluorines and hydrogens in the fluorinated alkane and the fluorinated alkene to be 40 mol % or less.

Perfluoroalkanes, perfluoroalkenes, and corresponding ethers having an oxygen between carbons thereon are often even more preferred. The ether having an oxygen between carbons on a fluorinated alkane or a fluorinated alkene refers overall to a fluorine-containing compound, although, as can be seen in Example 3, an alkyl or alkenyl which does not contain fluorine may also be included.

As described subsequently, it was found that desirable characteristics can be obtained also in cases where the fluorine-containing organic substance is monofluoromethane, difluoromethane, trifluoromethane or a mixture thereof.

The coating layer in the above description is formed from these fluorine-containing organic substances and, as shown in FIG. 1, is thought to have a structure similar to these fluorine-containing organic substances. In the present specification, these structures are called “fluorine-containing organic structures.” Aside from bonding with the treatment surface, bonds between the fluorine-containing organic structures may also arise as a result of reactions.

In the embodiments disclosed in this specification including the above, as when achieving ultra-low floating characteristics for a head slider, given the object of coating the treatment surface to a minimal thickness, it is preferable for the coating layer to be formed of a molecular monolayer. Also, in some cases, it is preferable for the coating layer to be formed of a horizontally oriented molecular monolayer. As explained in the subsequently described embodiments, because the fluorine-containing organic structures have a monolayer thickness of about 0.5 nm, it is preferable for the fluorine-containing organic structures that have bonded to the treatment surface to have a thickness which is at or below this value. These may all be understood as averages. The above can be achieved in the embodiments disclosed in this specification.

The other gas components making up the fluorine-containing organic substance-containing gas may be any components capable of forming the above coating layer, although it is generally preferable to avoid substances which absorb ultraviolet light, such as oxygen and water. Examples of other gas components include nitrogen, argon, neon and helium. In cases where oxygen or water is present, these should be held to not more than 50 ppm by weight.

No particular limitation is imposed on the type of ultraviolet light used for ultraviolet irradiation. Use may be made of UV-A (wavelength, 315 to 400 nm), UV-B (wavelength, 280 to 315 nm), UV-C (wavelength, 200 to 280 nm) or VUV (vacuum ultraviolet; wavelength, 10 to 200 nm). UV-C and VUV are preferred in terms of handleability. Any suitable light source may be used for these types of ultraviolet light. From a practical perspective, it is preferable to select a light source from the group consisting of low-pressure mercury vapor lamps, xenon excimer lamps, argon excimer lamps, krypton excimer lamps and combinations thereof.

The material making up the above treatment surface may be any material to which this treatment can be applied. In the case of the surface of a magnetic recording medium or head slider in a magnetic recording/playback device, as subsequently described, illustrative examples include DLC (diamond-like amorphous carbon), AlTiC (a sintered body of alumina and titanium carbide), silicon, and also zirconia, alumina, titanium carbide, sapphire, silica and tungsten carbide. Needless to say, the treatment surface may be the entire treatment surface (e.g., a magnetic recording medium or head slider), or a portion thereof. In some cases, nitrogen or the like is added to these treatment surfaces.

Because it is important for the relationship between the type of ultraviolet light and the material making up the treatment surface to be such that “the ultraviolet light generates photoelectrons from the treatment surface,” suitable combinations are possible. For example, when the treatment surface is a magnetic recording medium or head slider surface in a magnetic recording/playback device, as subsequently described, amorphous carbon (e.g., DLC) and AlTiC are often used. In such cases, a xenon excimer light is preferred as the ultraviolet light.

Also, concerning to the relationship between the energy of the ultraviolet light and the work function of a material making up the treatment surface, it is preferable for the former to be higher than the latter. The reason is that, under these conditions, photoelectrons which induce bonding of the fluorine-containing organic substance are readily generated. For example, in regards to amorphous carbon, because the FCA process (filtered cathodic arc process) has a larger work function than the CVD process (chemical vapor deposition process), sufficient treatment often cannot be carried out with light having a wavelength of 185 nm from a low-pressure mercury vapor lamp. In such cases, it is necessary to use light having a larger energy value. For example, it is more useful to use a short wavelength xenon excimer lamp (wavelength, 172 nm; vacuum ultraviolet) than the above-mentioned mercury vapor lamp.

The surface treatment process carried out in this way can be advantageously employed in a method of manufacturing a magnetic recording medium for a magnetic recording/playback device. Specifically, by incorporating into the method of manufacturing a magnetic recording medium the steps of providing a magnetic recording medium protective layer on a magnetic layer of a magnetic recording medium, and irradiating a surface of the magnetic recording medium protective layer with ultraviolet light in a gas containing a fluorine-containing organic substance so as form a coating layer on the surface, the coating layer may be utilized in place of a magnetic recording medium lubricating layer or as a portion of the lubricating layer. In this way, a solution can be provided for the problem of contaminant deposition and resin aggregation on the surface of a magnetic recording medium.

The surface treatment method carried out in this way can also be advantageously employed in a method of manufacturing a head slider for a magnetic recording/playback device. Specifically, by incorporating into the method of manufacturing a head slider the steps of providing a head slider protective layer on a magnetic layer of a head slider, and irradiating a surface of the head slider protective layer with ultraviolet light in a gas containing a fluorine-containing organic substance so as to form a coating layer on the surface, the coating layer may be utilized in place of a head slider lubricating layer or as a portion of the lubricating layer. In this way, a solution can be provided for the problem of contaminant deposition and resin aggregation on the surface of a head slider.

Moreover, the fact that, regardless of the type of process by which the above is achieved, effects like those of the above coating layer can be imparted so long as the above fluorine-containing organic structures are obtainable confirms the soundness of this approach. An illustrative, non-limiting, example of such a process is one that generates radicals or ions of the fluorine-containing organic structures (e.g., the irradiation of high-energy rays other than ultraviolet light).

This holds with regard to both magnetic recording media and head sliders, although a head slider having a recording transducer for carrying out recording to and/or playback from a magnetic recording medium, and also having a head slider protective layer on the head slider on a side facing the magnetic recording medium, and a covering formed on the head slider protective layer and including fluorine-containing organic structures composed of small molecules having a number of constituent atoms following deposition of three or four is a highly preferred application for the following reasons. That is, in addition to the fact that this covering may be utilized in place of a head slider lubricating layer or as a portion of the lubricating layer, and is able to provide a solution to the problem of contaminant deposition and resin aggregation on the surface of a head slider, it is highly desirable also in that a very thin film can be obtained. This appears to be attributable to the fact that this covering can be formed as a molecular monolayer.

The reason here for specifying “a covering . . . which includes fluorine-containing organic structures composed of small molecules having a number of constituent atoms following deposition of three or four” is that, as in the earlier explanation of bonding between fluorine-containing organic structures, fluorine-containing organic structures which are composed of small molecules in which the number of constituent atoms is three or four and are bonded to each other may also be present.

As will be explained later, it is preferable for covalent bonds that are monovalent or divalent to exist between the head slider protective layer and the fluorine-containing organic structures.

Also, it is preferable for the fluorine-containing organic structures making up the covering formed on the head slider protective layer to have the formula

.CHₙFₘ,

wherein the letters n and m stand for 0 or a positive integer and satisfy the conditions 0≦n≦2, 1≦m≦3 and 2≦(n+m)≦3, and the symbol “.” at left in the formula indicates a bond with the head slider protective layer. That is, —CH₂F₁, ═CH₁F₁, —CH₁F₂, ═CF₂ and —CF₃ are preferred.

Because the fluorine-containing organic structures are firmly attached to the treatment surface, the above head slider and recording medium, particularly the former, are especially useful in magnetic recording/playback devices of a type in which a state where a portion of the head slider and the recording medium come into contact inevitably arises. Specifically, they are especially useful in magnetic recording/playback devices which have a head slider and a recording medium and which employ a system wherein the relative position of a head slider with respect to the recording medium is detected by contact between a portion of the head slider and the recording medium, following which information is recorded on the recording medium or information is played back from the recording medium with the head slider and the recording medium in a non-contact state, or which employ a system in which information is recorded on the recording medium or information is played back from the recording medium with a portion of the head slider in contact with the recording medium.

Next, working examples and comparative examples are described in detail. The following measurement methods were used.

### Surface Free Energy

The surface free energy (SFE) was determined by measuring the contact angle between diiodomethane and water. Determination was carried by analysis in accordance with the geometric mean rule of D. K. Owens and R. C. Wendt.

In carrying out these determinations, γd stands for the SFE of the dispersed component, γp stands for the SFE of the polar component, and γtot stands for the sum of γd and γp. With regard to the measurement positions for surface free energy, as shown in FIG. 4, 0° was arbitrarily set on the disk-shaped treatment surface, measurements were carried out at the places indicated as 90° and 180° in FIG. 4, and the average of these measurements was used. When “SFE” is indicated by itself, this corresponds to γtot.

### Average Film Thickness of Coating Layer

Ψ and Δ were measured with an ellipsometer (beam radius on head, 100 μm×30 μm; He—Ne laser; incident angle, 70°). Based on these values, analysis was carried out using 1.3 as the refractive index for the coating layer and 0 as the extinction coefficient.

### Working Example 1

### Method of Creating an Ultrathin Film, Uniform and Low-Surface Free Energy Surface

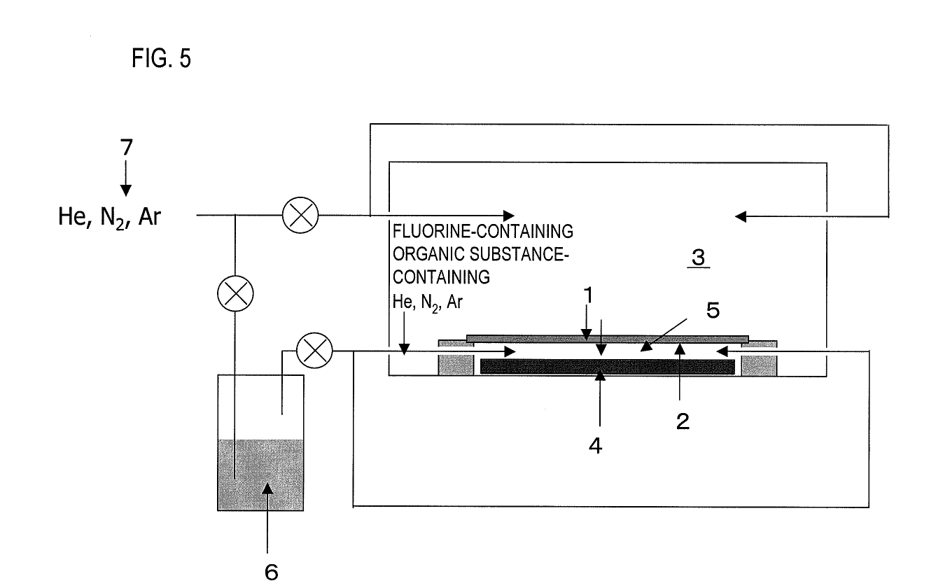

It was found that the desired surface can be created using the apparatus shown in FIG. 5, which is a simplified cross-sectional image of an apparatus for forming a treated surface on an object having a treatment surface. In FIG. 5, a magnetic recording medium having a magnetic layer with a protective layer thereon, but lacking a lubricating layer on the protective layer, is used as the object having a treatment surface. The free surface of the protective layer was used as the treatment surface. A protective layer composed of amorphous carbon (film thickness, 3.5 nm) formed by the CVD method was used.

A magnetic recording medium 1 has been placed in a chamber 3 with a treatment surface 2 facing downward, and an ultraviolet lamp 4 is disposed on the bottom side of the treatment surface 2 within the chamber 3 so as to be able to irradiate the treatment surface 2. A gas containing a fluorine-containing organic substance is mixed with a suitable gas (exemplified by helium, argon and nitrogen in FIG. 1), and flows into a space 5 between the treatment surface 2 and the ultraviolet lamp 4. In FIG. 5, the gas 7 has been passed through a liquid fluorine-containing organic substance 6, although other methods are also acceptable. In some cases, volatilization or evaporation of the fluorine-containing organic substance may be promoted by heating the fluorine-containing organic substance, the fluorine-containing organic substance-containing gas or the like, or by reducing the pressure in the system. Also, in cases where substances which inhibit the action of ultraviolet light such as oxygen are present within the system, it is preferable to reduce or eliminate these. In the case of oxygen, suppression to a level of 50 ppm by weight or below is preferred.

The treatment surface is treated by carrying out ultraviolet irradiation under these conditions.

It should be understood that FIG. 1 is merely illustrative, and that improvements and modifications to this apparatus, such as modification to a continuous treatment apparatus, will be readily apparent to persons skilled in the art.

### Working Example 2

### Use on a Magnetic Recording Medium

The surface of a magnetic recording medium was treated using the apparatus described in Working Example 1. The magnetic recording medium used had a magnetic layer on which was provided a magnetic recording medium protective layer composed of DLC produced by the FCA method. The free surface of this magnetic recording medium protective layer was used as the treatment surface.

Using n-perfluoroheptane as the fluorine-containing organic substance, nitrogen gas containing 10 wt % of n-perfluoroheptane was introduced at a flow rate of 100 mL/min into a nitrogen-flushed chamber 3. A xenon excimer lamp was used as the ultraviolet irradiation source. The ultraviolet energy in this case was 7.2 eV, which was larger than the work function for DLC of about 6 eV. This value of 6 eV, when converted to the wavelength of ultraviolet light using the formula E=hv=h/λ (where h is Plank's constant, and λ is the wavelength), is about 210 nm.

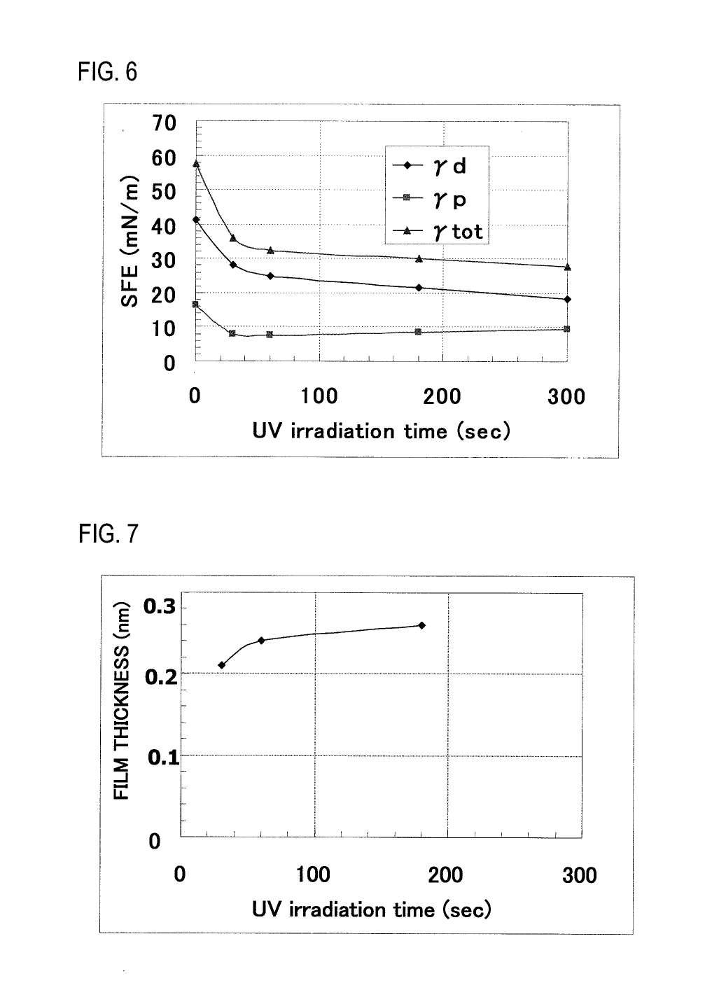

The results obtained are shown in FIGS. 6 and 7. As shown in FIG. 6, it was found that the surface free energy decreased with increasing ultraviolet irradiation time, and that a coating layer had formed.

FIG. 7 shows the coating layer thickness (thickness of the layer of applied material) at that time. Because the Van der Waals radius of carbon in n-perfluoroheptane is 0.14 nm and the distance of fluorine atoms on the same carbon in repeating —CF₂— bonds (not including Van der Waals diameter) is 0.18 nm, the layer thickness in the monolayer portion of the coating layer calculated from these values is 0.18+0.14×2=0.46 nm (about 0.5 nm). Therefore, the results obtained appear to mean that about one-half of the treated surface of the magnetic recording medium has been coated.

### Working Example 3

### Use on a Magnetic Recording Medium

Aside from using ethyl n-perfluorobutyl ether (C₄F₉OC₂H₅) instead of n-perfluoroheptane as the fluorine-containing organic substance, a similar investigation was carried out as in Working Example 1.

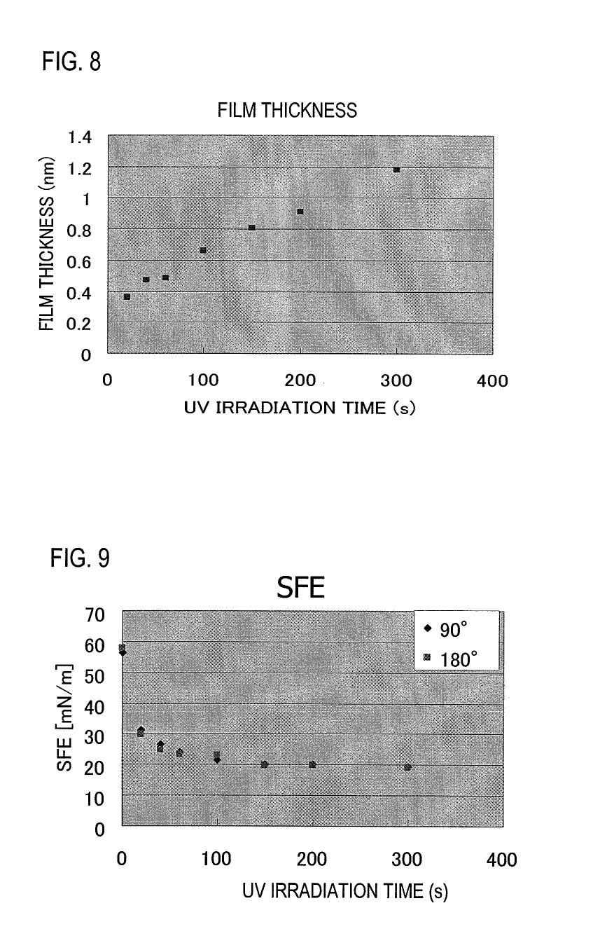

The results are shown in FIGS. 8 to 10. In FIGS. 8 to 10, the diamonds represent measured values obtained at 90° places in FIG. 4, and the squares represent measured values obtained at 180° places in FIG. 4.

It is apparent from FIG. 8 that the film thickness can be controlled by the ultraviolet irradiation time. Values larger than the coating monolayer thickness of about 0.5 nm described in Working Example 2 were also obtained. This appears to mean that an additional coating layer has bonded onto the coating monolayer, forming a layered state.

Also, it is apparent from FIG. 9 that the SFE converges to a fixed value. Given that a large change in the SFE is inconceivable even when the coating layer goes from being a single layer to being a plurality of layers, it is probably fair to conclude that at the time of this convergence the first coating layer is complete. At this convergence time, the ultraviolet irradiation time is about 100 seconds. Applying this to FIG. 8, a value of about 0.7 nm, which is close to the value of approximately 0.5 nm that is the thickness of the coating monolayer, occurs at about 100 seconds. From this standpoint as well, it can be demonstrated that the layer thickness of the coating monolayer has been achieved at this conversion time.

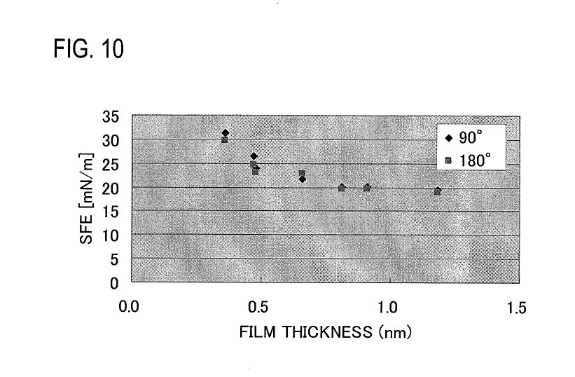

FIG. 10 is a graph showing the relationship between the SFE and the coating layer thickness obtained in FIGS. 8 and 9. From this graph, it is apparent that a SFE of 25 mN/m or less is obtained at film thicknesses of from about 0.5 to about 0.7 nm. In the lubricating layers provided on protective layers at present, a film thickness of about 1 nm is necessary to achieve a SFE of 25 mN/m. Given that, at smaller film thicknesses than this, the problems of contaminant adhesion on the surface of the lubricating layer and resin aggregation on the lubricating layer generally occur together with the rise in the SFE value, the above may be regarded as a result that provides a solution to these problems.

When extended head floating tests were carried out on samples having a SFE of 25 mN/m and a film thickness of 0.5 nm, contaminants were observed on the head surface in untreated samples, but were not observed in samples under the present conditions. Also, even when these samples were dipped in a fluorinated organic solvent, such as Vertrel XF (available from DuPont-Mitsui Fluorochemical Co., Ltd.), firm adhesion of the coating layer was confirmed.

### Working Example 4

### Use on a Head Slider

In this working example, a fluorine-containing organic substance was chemically bonded onto a head slider. The fluorine-containing organic substance was the same as that used in Working Example 3, and treatment similar to that in Working Example 3 was carried out.

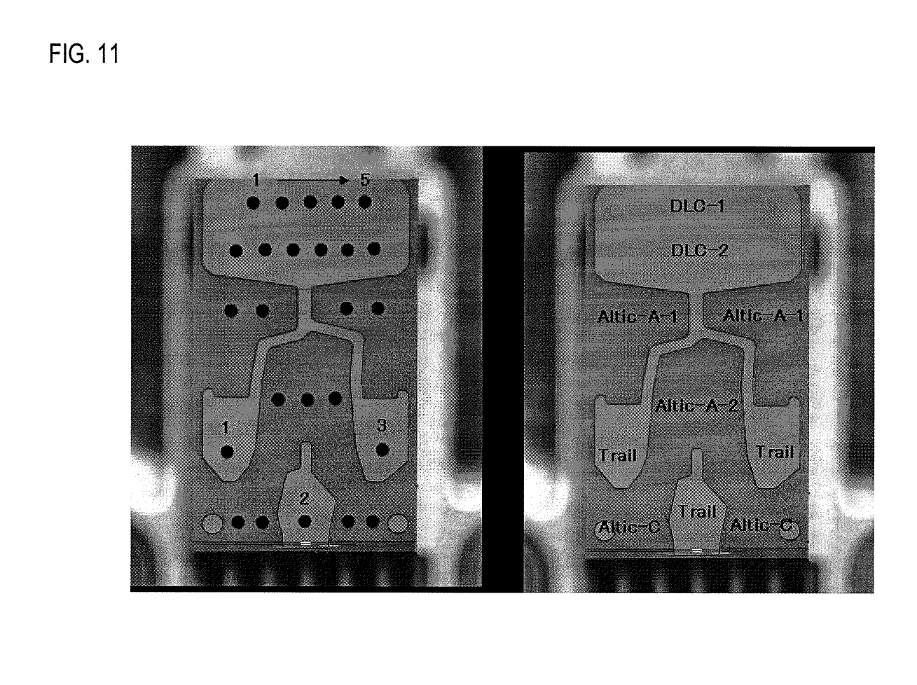

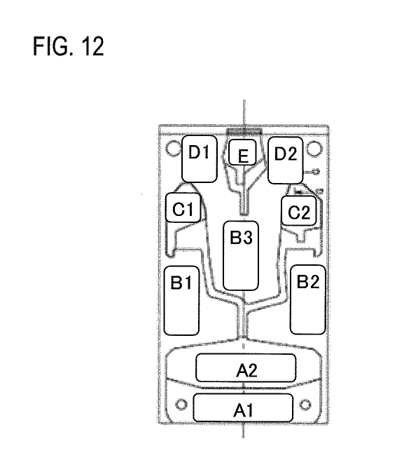

FIG. 11 shows photographs of the surface of the head slider used that faces the magnetic recording medium. The black dots in the photograph at left are the surface free energy measurement positions. In the photograph at right, the names of the measurement regions are indicated. “DLC” refers to portions where a protective layer made of diamond-like amorphous carbon was provided, “AlTiC” refers to portions where a protective layer made of a sintered body of alumina and titanium carbide was provided, and “Trail” refers to portions where a protective layer made of a diamond-like amorphous carbon similar to DLC was provided. A lubricating layer was not provided on the protective layer. FIG. 12 shows the film thickness measuring regions.

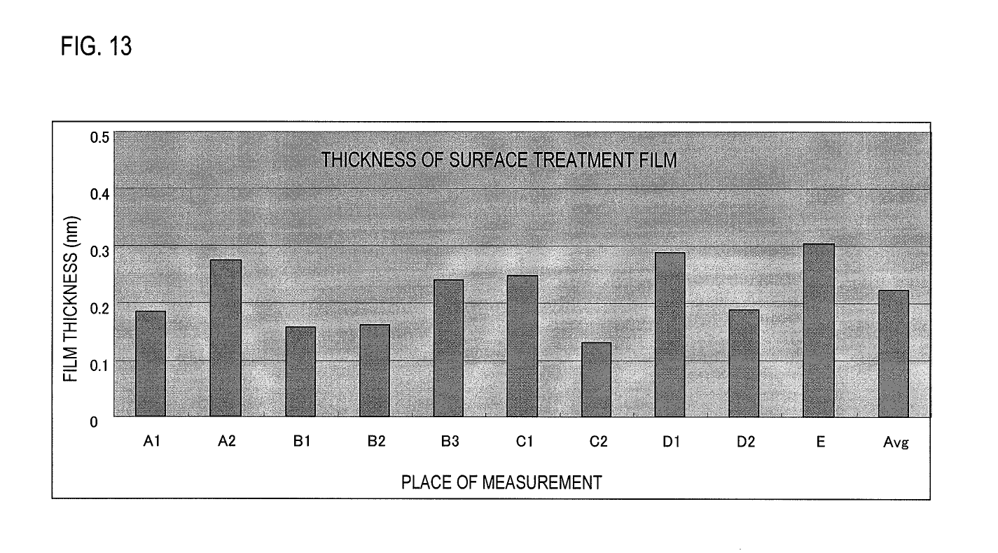

Table 1 shows the results of SFE measurements, and FIG. 13 shows the results of film thickness measurements. Because the untreated SFE is about 45 mN/m, it will be appreciated from Table 1 and FIG. 13 that ultrathin film, low surface free energy surfaces formed on the ultrathin films as a result of this surface treatment.

TABLE 1
Surface free energy (mN/m)

| | γd | γp | γtot |
|---|---|---|---|
| DLC-1 | 21.6 | 6.0 | 27.6 |
| DLC-2 | 26.3 | 8.3 | 34.6 |
| Altic-A-1 | 22.0 | 5.0 | 27.0 |
| Altic-A-2 | 22.2 | 5.1 | 27.3 |
| Altic-C | 22.6 | 4.9 | 27.5 |
| TRAIL-1 | 25.4 | 9.5 | 34.9 |
| TRAIL-2 | 26.1 | 9.2 | 35.3 |
| TRAIL-3 | 26.1 | 9.0 | 35.1 |

### Working Example 5

### Bonding State of Small-Molecule, Fluorine-Containing Organic Structures to Treatment Surface

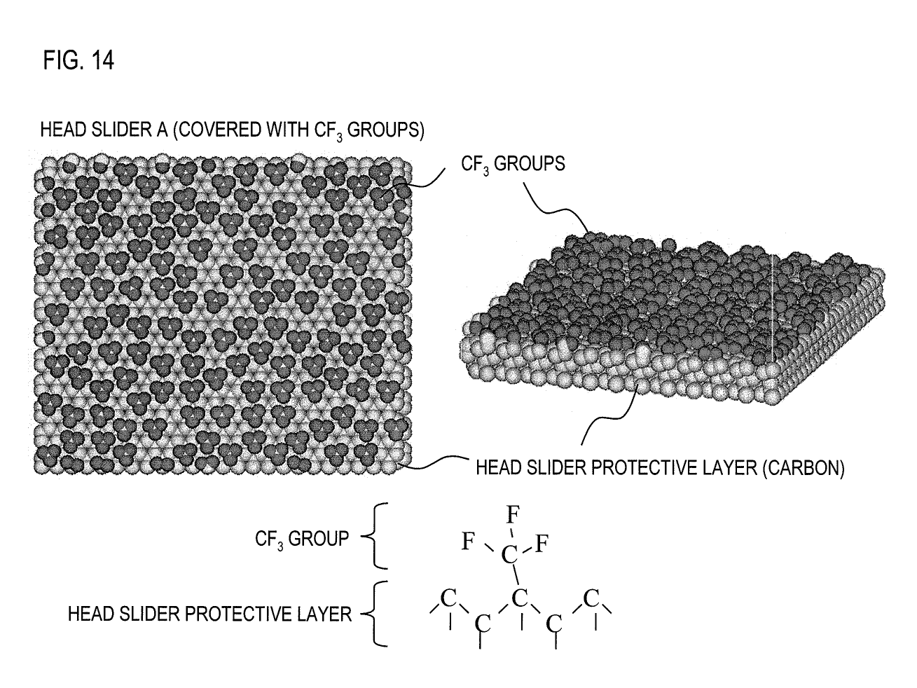

FIG. 14 is a schematic diagram showing the state of a small molecule, fluorine-containing organic structure on a head slider protective layer (treatment surface). The image at left in FIG. 14 is the head slider protective layer surface (what may be called the head slider floating surface) as seen from in front, the image at right in FIG. 14 is a bird's eye view of the same, and the image at the bottom in FIG. 14 shows the atom bonding state.

As shown at the bottom of FIG. 14, a protective layer made of carbon is formed on the head slider protective layer surface, and the surface of the protective layer is covered with CF₃ groups. The carbons of the CF₃ groups and the carbons of the protective layer are thought to be bonded by covalent bonds. The method for creating the surface of such a head slider protective layer may involve, for example, exposing the floating surface of the head slider to ultraviolet irradiation in a fluoromethane-containing gas. This covering firmly adhered even after the head slider was treated by 30 seconds of immersion in Vertrel XF-UP (available from DuPont-Mitsui Fluorochemical Co., Ltd.) under stirring.

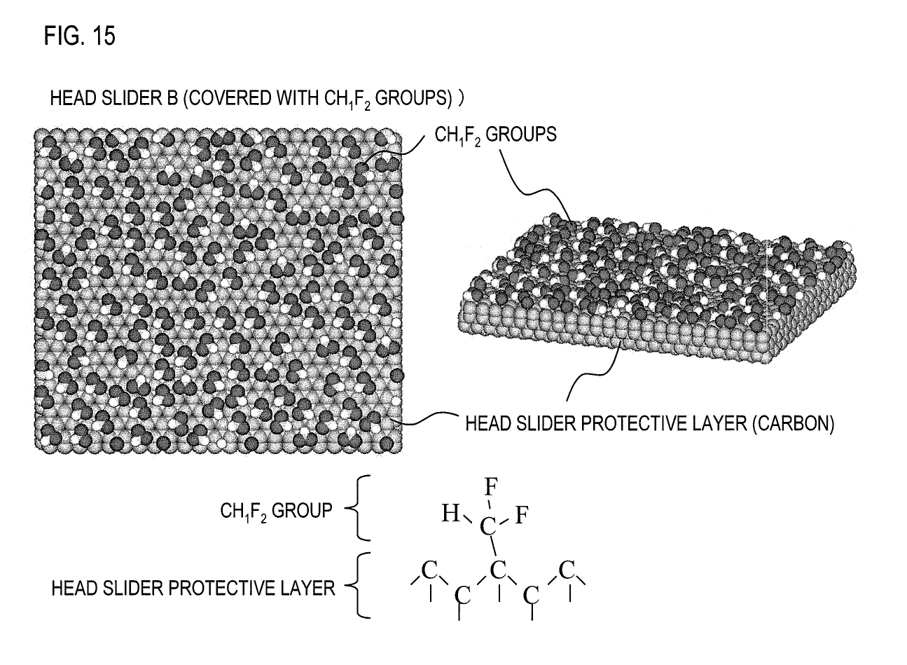

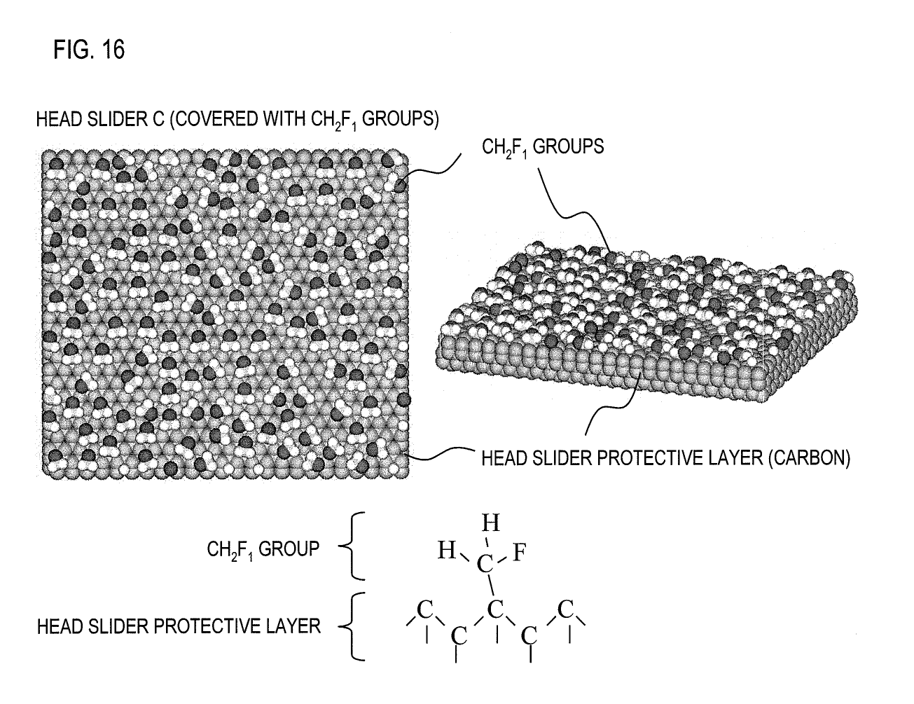

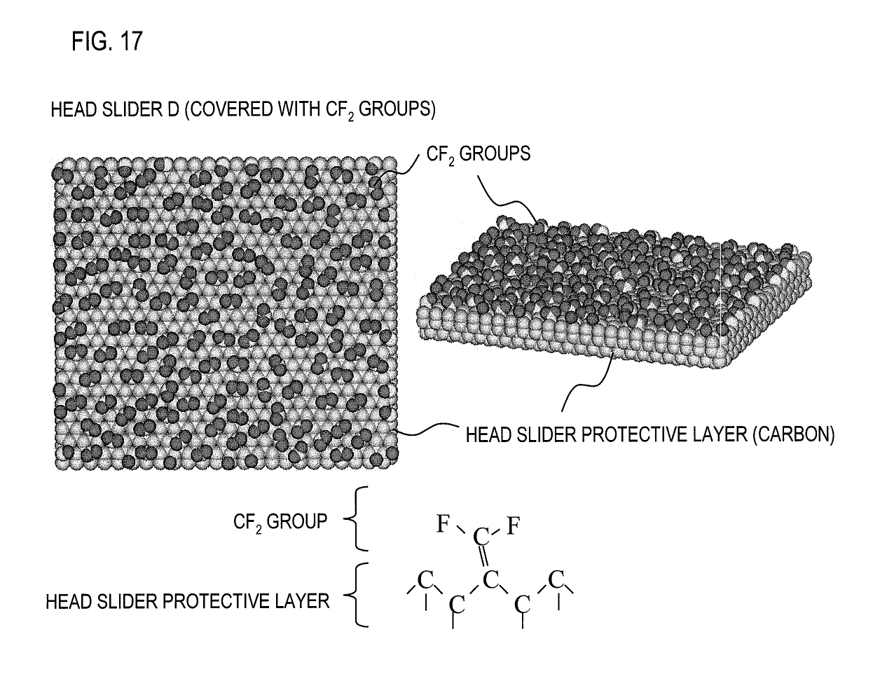

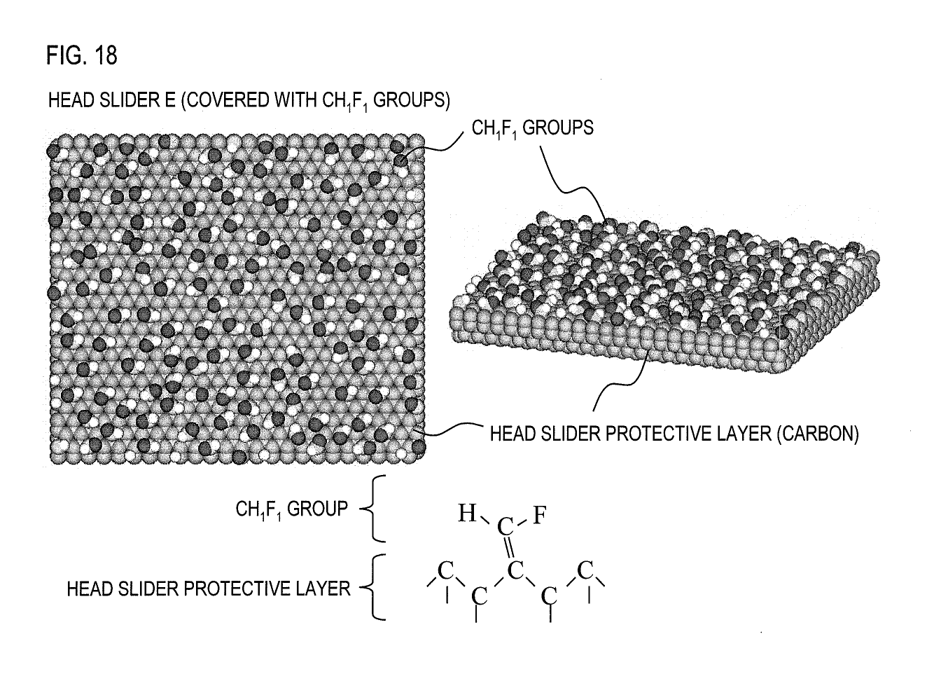

Similarly, FIG. 15 shows a surface coated with CH₁F₂ groups, FIG. 16 shows a surface coated with CH₂F₁ groups, FIG. 17 shows a surface coated with CF₂ groups, and FIG. 18 shows a surface coated with CH₁F₁ groups.

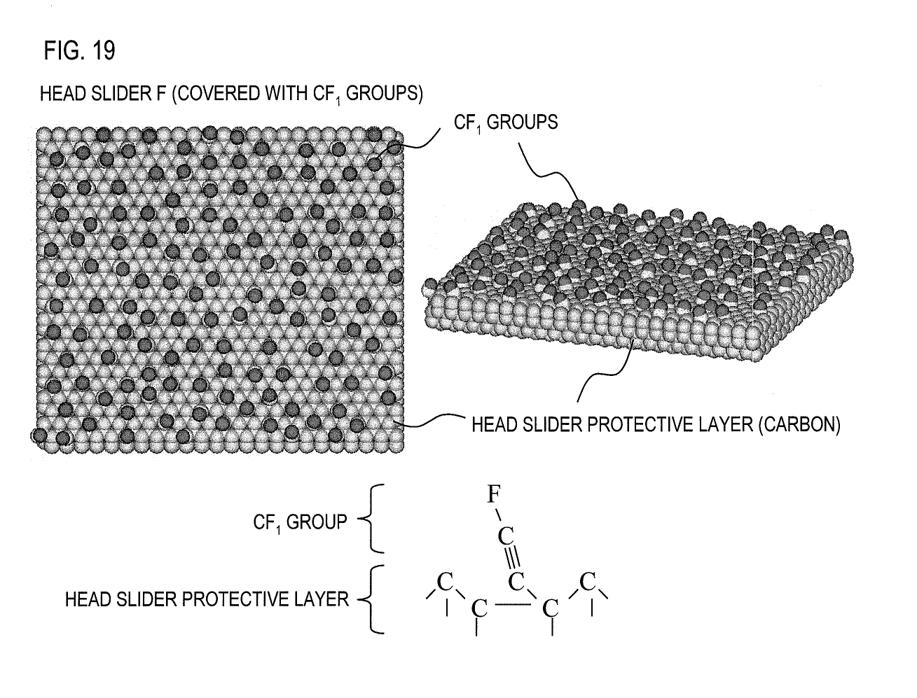

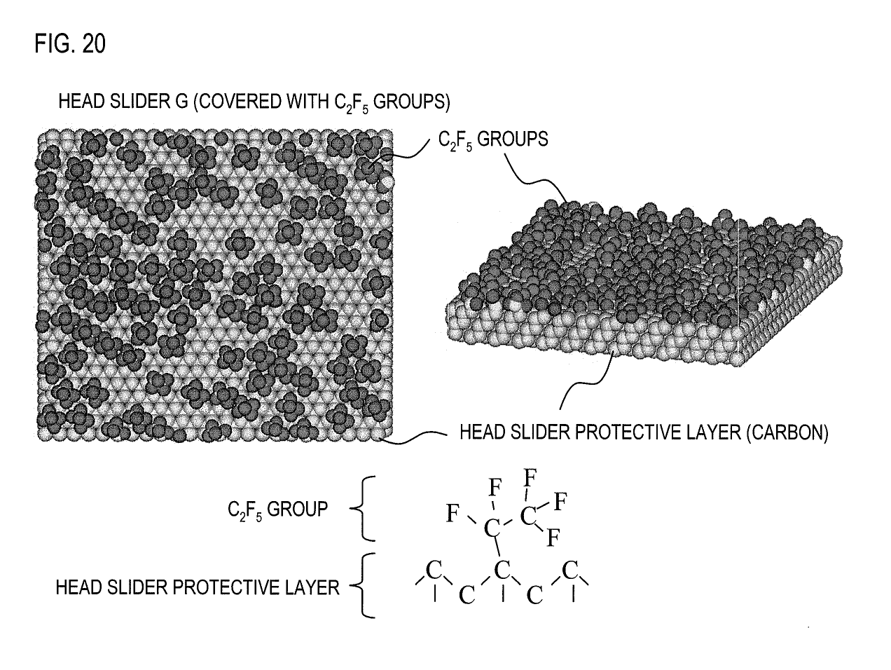

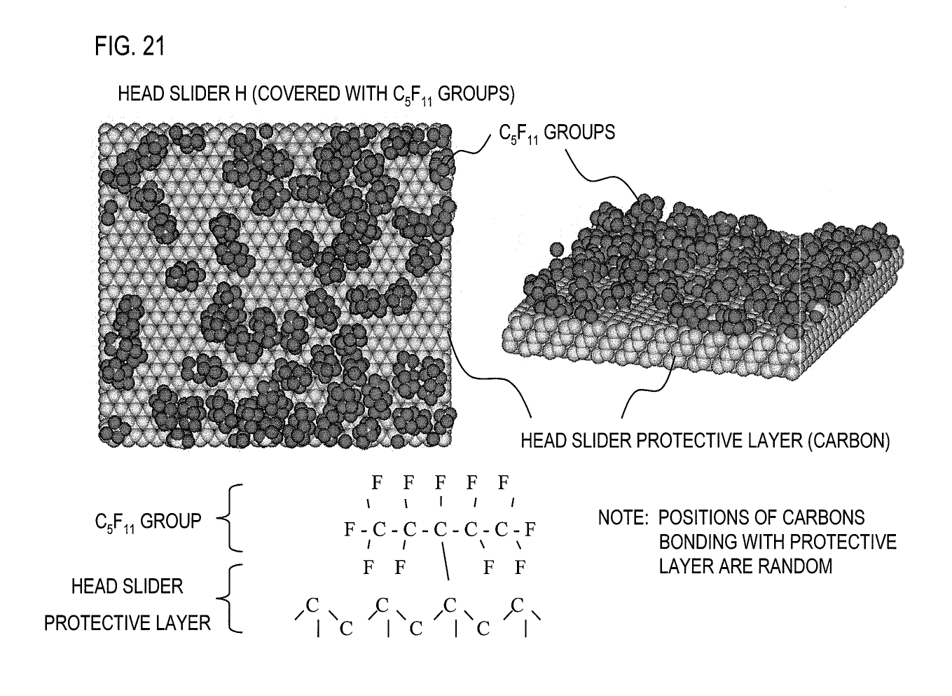

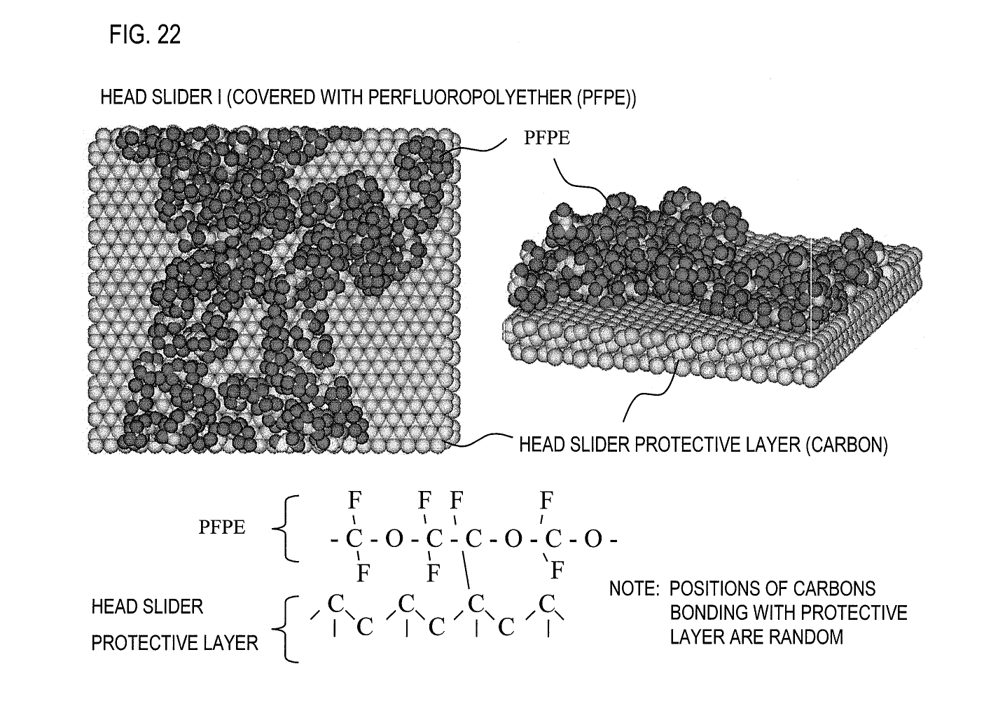

To verify the effects of the embodiments in this specification, the friction characteristics when the recording medium and the head slider come into contact were calculated using numerical analysis by a molecular dynamics method. FIGS. 19 to 22 are schematic diagrams showing the states of fluorine-containing organic structures on head slider protective layers (treatment surfaces) used for comparison with the embodiments of the present specification (FIGS. 14 to 18). FIG. 19 shows a head slider protective layer whose surface is covered with CF₁ groups, FIG. 20 shows a head slider protective layer whose surface is covered with C₂F₅ groups, FIG. 21 shows a head slider protective layer whose surface is covered with C₅F₁₁ groups, and FIG. 22 shows a head slider protective layer whose surface is covered with perfluoropolyether (PFPE). The PFPE used as the covering in FIG. 22 had the following molecular formula.

CF₃O—[C₂F₄O]₂₀[CF₂O]₂₀—CF₃

However, as shown at the bottom of FIG. 22, some of the carbons in the PFPE molecule are chemically bonded with the protective layer on the head slider so as not to move under the effect of friction.

Six layers of diamond crystal composed of 3,456 carbon atoms were used as a molecular model of a carbon protective layer. However, because ordinary protective layers are made of diamond-like carbon (DLC), which has a lower density than diamond, in order to have the density match that of DLC, the bond length between carbon atoms was set to 1.92 Å, which is longer than the standard bond length of 1.54 Å. The sizes of the molecular models of the protective layer were all 7.52 nm×6.51 nm.

The head sliders that were subjected to the surface modification in FIGS. 14 to 22 were respectively labeled as head sliders A to I, and the frictional stress of each was evaluated. The fluorine-containing organic structures that were used are all shown in Table 2.

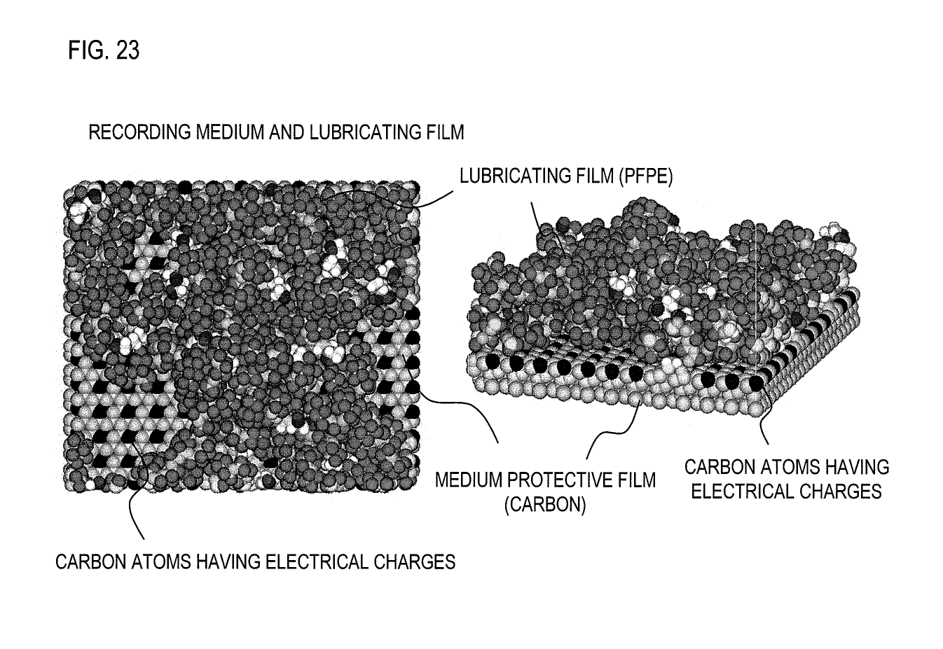

Independent of the head slider, molecular models of the protective layer and lubricating film on the recording medium were created (FIG. 23). The carbon protective layer on the recording medium had the same structure as that on the head slider, but an electrical charge of ±0.3 e was applied to one-quarter of the surface most carbon atoms, or a total of 144 places, inducing the adsorption of lubricant molecules by electrostatic forces. PFPE having hydroxyl groups was used as the lubricant. The molecular weight was 2,510, and the molecular formula was as follows.

X—CF₂O—[C₂F₄O]₁₂[CF₂O]₁₂—CF₂—X

Here, X represents CH₂—OCH₂—CH(OH)CH₂OH.

The number of lubricant molecules on the recording medium protective layer is 20, and the average film thickness is 1.0 nm. In 13 of the 20 lubricant molecules (65%), a portion of the molecule is chemically bonded to the medium protective layer so as not to move under the effect of friction.

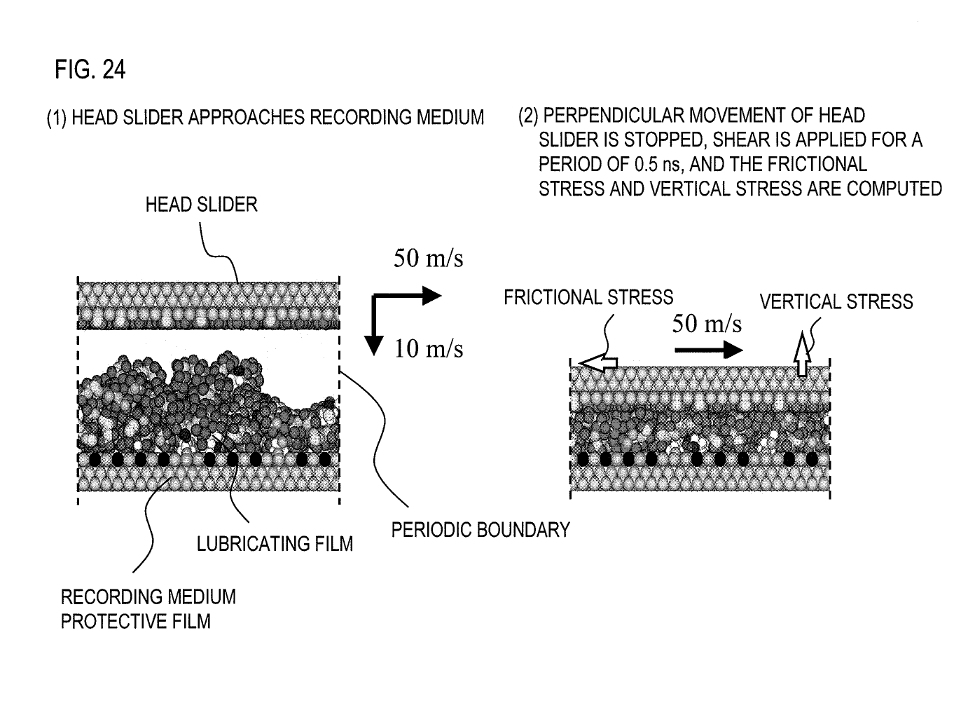

FIG. 24 shows the method of calculating the frictional characteristics by the molecular dynamics method. First, while moving the head slider molecular models shown in FIGS. 14 to 22 in the horizontal direction, the recording medium shown in FIG. 23 was brought closer at an approach speed of 10 m/s.

When the head slider had come into contact with the lubricating film and the gap between the head slider and the recording medium protective layer had reached a constant value, the approach velocity was set to 0 m/s, a shear was applied in this state for a period of 0.5 ns, and the changes over time in the vertical stress and frictional stress that acted on the protective layer were calculated.

At this time, because so-called periodic boundary conditions are used wherein molecules that flow out from one edge of the region under analysis flow into the edge on the opposite side, a flat plane of substantially infinite extent is being analyzed. The speed of movement by the head slider in the horizontal direction was set at 50 m/s. All the carbon atoms in the protective layer converged to this speed. Also, all the carbon atoms in the protective layer of the recording medium converged to a speed of 0 m/s. The temperature of the system during analysis was adjusted to a constant temperature of 300 K using the loose coupling method.

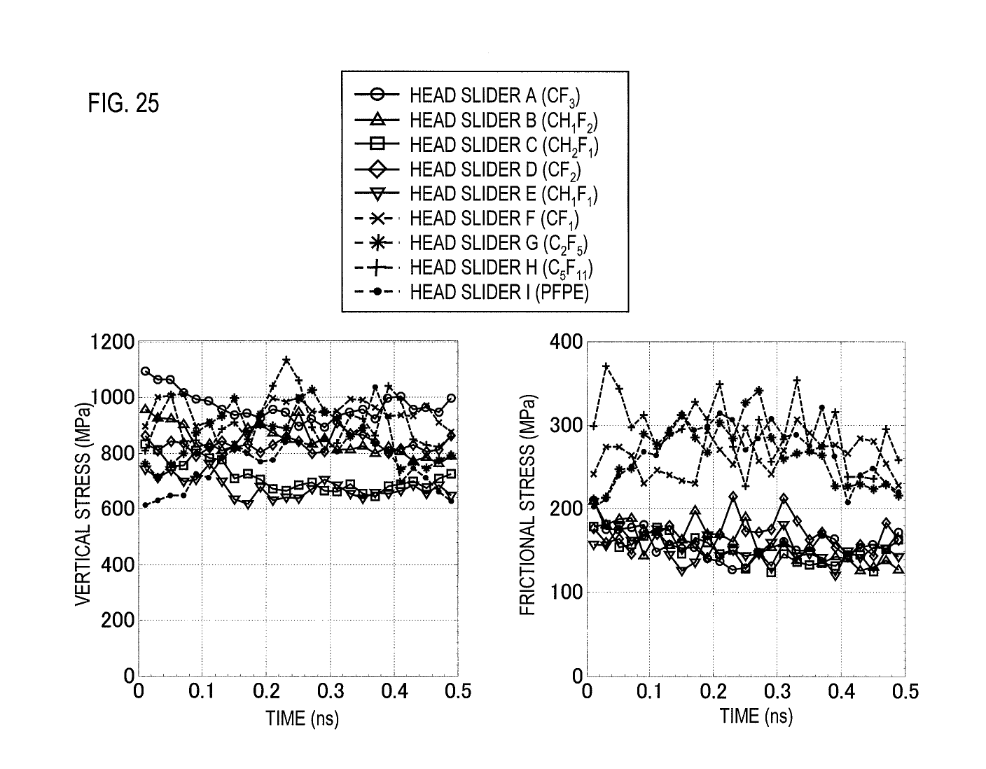

Numerical analysis was carried out under the above conditions, and changes in the frictional stress and the vertical stress on each head slider were calculated. The results are shown in FIG. 25. The graph at left in FIG. 25 shows the change over time in vertical stress, and the graph at right in FIG. 25 shows the change over time in frictional stress. From the results in FIG. 25, the average value at 0.4 to 0.5 ns after judging that each type of stress has converged was calculated, and the coefficient of friction was computed from the vertical stress and the frictional stress.

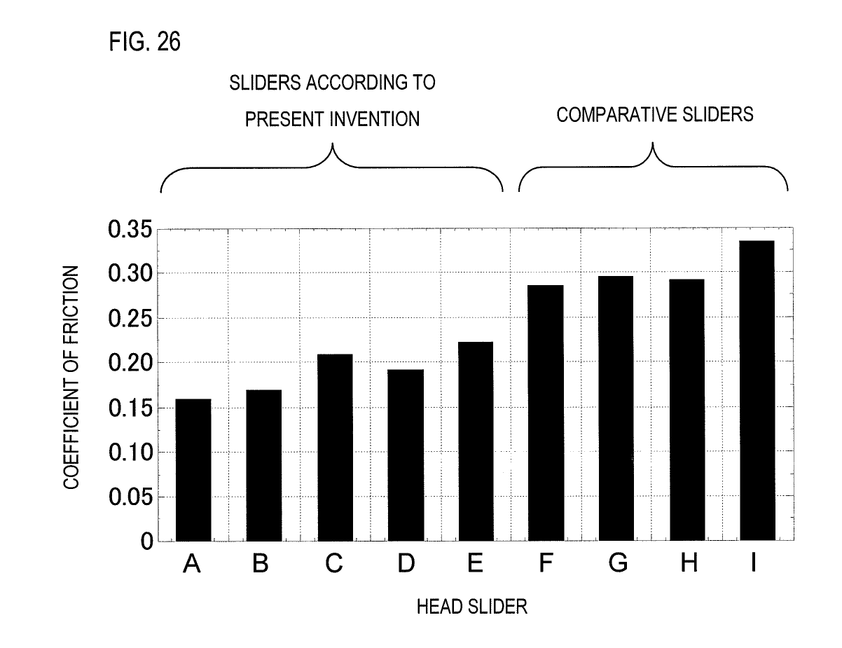

The results are summarized in Table 3 and FIG. 26. The coefficient of friction ranged from 0.285 to 0.334, or about 0.3, on head sliders F to I. By comparison, much lower results were obtained for head sliders A to E, on which the coefficient of friction ranged from 0.160 to 0.222. The reason for this disparity is thought to be as follows. In head sliders A to E, which were covered with small molecules, as can be seen in FIGS. 14 to 18, the fluorine-containing organic structures on the head slider protective film are small, resulting in a high surface planarity. By contrast, in head sliders G to I, as can be seen in FIGS. 20 to 22, the number of atoms in the covering molecules has increased, enlarging the surface irregularity of the fluorine-containing organic structure. As a result, dragging of the lubricant molecules on the recording medium becomes more frequent, increasing the coefficient of friction.

Also, as can be seen in FIG. 19, although the molecules on the head slider F are small, the coefficient of friction has increased. Here, the increase in the coefficient of friction appears to be due to the fact that the CF₁ groups extend vertically with respect to the surface and have a relatively strong flexural rigidity.

TABLE 2

| | Fluorine-containing |
|---|---|
| Head Slider Name | organic structure |
| Head Slider A | •CH₃ |
| Head Slider B | •CH₁F₂ |
| Head Slider C | •CH₂F₁ |
| Head Slider D | •CF₂ |
| Head Slider E | •CH₁F₁ |
| Head Slider F | •CF₁ |
| Head Slider G | •C₂F₅ |
| Head Slider H | •C₅F₁₁ |
| Head Slider I | •PFPE |

TABLE 3

| | Fluorine- | | | |
|---|---|---|---|---|
| Head | containing | Pressing | Frictional | |
| Slider | Organic | Stress | stress | Coefficient |
| Name | Structure | (MPa) | (MPa) | of Friction |
| Head | •CH₃ | 973 | 156 | 0.160 |
| Slider A | | | | |
| Head | •CH₁F₂ | 783 | 133 | 0.170 |
| Slider B | | | | |
| Head | •CH₂F₁ | 698 | 146 | 0.209 |
| Slider C | | | | |
| Head | •CF₂ | 824 | 158 | 0.192 |
| Slider D | | | | |
| Head | •CH₁F₁ | 667 | 148 | 0.222 |
| Slider E | | | | |
| Head | •CF₁ | 925 | 263 | 0.285 |
| Slider F | | | | |
| Head | •C₂F₅ | 763 | 225 | 0.295 |
| Slider G | | | | |
| Head | •C₅F₁₁ | 870 | 253 | 0.291 |
| Slider H | | | | |
| Head | •PFPE | 688 | 230 | 0.334 |
| Slider I | | | | |

As shown and described above, in a head slider with a recording transducer for carrying out recording to and/or playback from a magnetic recording medium, it was found that by providing the head slider with, on a side thereof facing the magnetic recording medium, a head slider protective layer and by forming, on the head slider protective layer, a covering which includes fluorine-containing organic structures composed of small molecules having a number of constituent atoms following deposition of three or four, it is possible to reduce the surface free energy on the floating surface of the head slider and at the same suppress a rise in the coefficient of friction. The effect achieved as a result appears to be one where, even when the head slider and the recording medium come into contact, excessive friction does not arise on the head slider, thus making it possible to minimize the occurrence of malfunctions.

The inventions appearing in the following addenda may be derived from the subject matter disclosed above.

### Addendum 1:

A surface treatment method comprising:

irradiating a treatment surface with ultraviolet light in a gas containing a fluorine-containing organic substance so as to form a coating layer on the treatment surface.

### Addendum 2:

The surface treatment method of Addendum 1, wherein the fluorine-containing organic substance is selected from the group consisting of C₁₋₁₀ fluorinated alkanes, C₁₋₁₀ fluorinated alkenes, corresponding ethers having an oxygen between carbons thereon, and mixtures thereof.

### Addendum 3:

The surface treatment method of Addendum 2, wherein the fluorine-containing organic substance is monofluoromethane, difluoromethane, trifluoromethane, or a mixture thereof.

### Addendum 4:

The surface treatment method of any one of Addenda 1 to 3, wherein the ultraviolet light has an energy which is higher than the work function of a material making up the treatment surface.

### Addendum 5:

The surface treatment method of any one of Addenda 1 to 4, wherein the coating layer has an average thickness of not more than 0.5 nm.

### Addendum 6:

A method of manufacturing a magnetic recording medium for a magnetic recording/playback device, the method including:

providing a magnetic recording medium protective layer on a magnetic layer of the magnetic recording medium; and

irradiating a surface of the magnetic recording medium protective layer with ultraviolet light in a gas containing a fluorine-containing organic substance so as to form a coating layer on the surface.

### Addendum 7:

The magnetic recording medium manufacturing method of Addendum 6, wherein the fluorine-containing organic substance is selected from the group consisting of C₁₋₁₀ fluorinated alkanes, C₁₋₁₀ fluorinated alkenes, corresponding ethers having an oxygen between carbons thereon, and mixtures thereof.

### Addendum 8:

The magnetic recording medium manufacturing method of Addendum 6 or 7, wherein the ultraviolet light has an energy which is higher than the work function of a material making up the treatment surface.

### Addendum 9:

The magnetic recording medium manufacturing method of any one of Addenda 6 to 8, wherein the coating layer has an average thickness of not more than 0.5 nm.

### Addendum 10:

A method of manufacturing a head slider for a magnetic recording/playback device, the method including:

providing a head slider protective layer on a magnetic layer of the head slider; and

irradiating a surface of the head slider protective layer with ultraviolet light in a gas containing a fluorine-containing organic substance so as to form a coating layer on the surface.

### Addendum 11:

The head slider manufacturing method of Addendum 10, wherein the fluorine-containing organic substance is monofluoromethane, difluoromethane, trifluoromethane, or a mixture thereof.

### Addendum 12:

The head slider manufacturing method of Addendum 10 or 11, wherein the ultraviolet light has an energy which is higher than the work function of a material making up the treatment surface.

### Addendum 13:

The head slider manufacturing method of any one of Addenda 10 to 12, wherein the coating layer has an average thickness of not more than 0.5 nm.

### Addendum 14:

A magnetic recording medium comprising:

a magnetic layer; and

a magnetic recording medium protective layer which lies on the magnetic layer,

the magnetic recording medium further comprising a coating layer formed on a surface of the magnetic recording medium protective layer serving as the treatment surface, by carrying out ultraviolet irradiation according to the method of any one of Addenda 1 to 5.

### Addendum 15:

A head slider comprising:

a recording transducer for carrying out recording to and/or playback from a magnetic recording medium,

the head slider further comprising:

a head slider protective layer on a head slider surface facing the magnetic recording medium; and

a coating layer formed on a surface of the head slider protective layer serving as the treatment surface, by carrying out ultraviolet irradiation according to the method of any one of Addenda 1 to 5.

### Addendum 16:

A head slider comprising:

a recording transducer for carrying out recording to and/or playback from a magnetic recording medium,

the head slider further comprising:

a head slider protective layer on the head slider on a side facing the magnetic recording medium; and

a covering formed on the head slider protective layer and including fluorine-containing organic structures composed of small molecules having a number of constituent atoms following deposition of three or four.

### Addendum 17:

The head slider of Addendum 16, wherein covalent bonds that are monovalent or divalent exist between the head slider protective layer and the fluorine-containing organic structures.

### Addendum 18:

The head slider of Addendum 16 or 17, wherein the fluorine-containing organic structures making up the covering formed on the head slider protective layer have the formula

.CHₙFₘ,

wherein the letters n and m stand for 0 or a positive integer and satisfy the conditions 0≦n≦2, 1≦m≦3 and 2≦(n+m)≦3, and the symbol “.” at left in the formula represents a bond with the head slider protective layer.

### Addendum 19:

A magnetic recording/playback device having the head slider of any one of Addenda 15 to 18, wherein the magnetic recording/playback device employs a system in which, following detection of a relative position of the head slider with respect to a recording medium by contact between a portion of the head slider and the recording medium, information recording to the recording medium or information playback from the recording medium is carried out with the head slider and the recording medium in a non-contact state.

### Addendum 20:

A magnetic recording/playback device having the head slider of any one of Addenda 15 to 18, wherein the magnetic recording/playback device employs a system in which information recording to a recording medium or information playback from the recording medium is carried out with a portion of the head slider in contact with the recording medium.

1. A surface treatment method comprising:
irradiating a treatment surface with ultraviolet light in a gas containing a fluorine-containing organic substance so as to form a coating layer on the treatment surface.

2. The method of claim 1, wherein the fluorine-containing organic substance is selected from the group consisting of C₁₋₁₀ fluorinated alkanes, C₁₋₁₀ fluorinated alkenes, corresponding ethers having an oxygen between carbons thereon, and mixtures thereof.

3. A magnetic recording medium comprising:
a magnetic layer; and
a magnetic recording medium protective layer which lies on the magnetic layer,
the magnetic recording medium further comprising a coating layer formed on a surface of the magnetic recording medium protective layer serving as the treatment surface, by carrying out ultraviolet irradiation according to the method of claim 1.

4. A head slider comprising:
a recording transducer for carrying out recording to and/or playback from a magnetic recording medium,
the head slider further comprising:
a head slider protective layer on a head slider surface facing the magnetic recording medium; and
a coating layer formed on a surface of the head slider protective layer serving as the treatment surface, by carrying out ultraviolet irradiation according to the method of claim 1.

5. A head slider comprising:
a recording transducer for carrying out recording to and/or playback from a magnetic recording medium,
the head slider further comprising:
a head slider protective layer on the head slider on a side facing the magnetic recording medium; and
a covering formed on the head slider protective layer and including fluorine-containing organic structures composed of small molecules having a number of constituent atoms following deposition of three or four.

6. The head slider of claim 5, wherein covalent bond that is monovalent or divalent exists between the head slider protective layer and the fluorine-containing organic structures.

7. The head slider of claim 5, wherein the fluorine-containing organic structures making up the covering formed on the head slider protective layer have the formula
.CHₙFₘ,
wherein the letters n and m stand for 0 or a positive integer and satisfy the conditions 0≦n≦2, 1≦m≦3 and 2≦(n+m)≦3, and the symbol “.” at left in the formula represents a bond with the head slider protective layer.
